(19) United States
(12) Patent Application Publication
(10) Pub. No.: US 2003/0082921 A1
(43) Pub. Date: May 1, 2003

(54) Method for eliminating particle source

(76) Inventor: Chun-Ling Peng, Hsinchu Hsien (TW)

Correspondence Address: J.C. Patents, Inc., Suite 250, 4 Venture, Irvine, CA, 92618, US

(21) Appl. No.: 10/015,448

(22) Filed: Dec. 12, 2001

(30) Foreign Application Priority Data
Oct. 29, 2001 (TW) 90126671

(51) Int. Cl. H01L 21/302; H01L 21/461

(52) U.S. Cl. 438/710

(57) ABSTRACT

A method for eliminating the particle source is provided, which is suitably used in the etching process of a silicon oxide layer on the wafer. In this method, the wafer is degassed under a first temperature higher than the room temperature and then cooled down to a second temperature such as the room temperature. Thereafter, the silicon oxide layer is etched.

### CROSS-REFERENCE TO RELATED APPLICATION This application claims the priority benefit of Taiwan application serial no. 90126671, filed Oct. 29, 2001.

### BACKGROUND OF THE INVENTION

1. Field of Invention

The present invention relates to a method for eliminating a particle source. More particularly, the present invention relates to a method for decreasing the amount of the particles generated during etching a silicon oxide layer on a wafer.

2. Description of Related Art

In the semiconductor process, decreasing the amount of particles generated during the process is a major issue. For instance, the following process of forming a damascene structure in a silicon oxide layer frequently suffers from particle contamination. In this process, a substrate is provided with a silicon oxide layer on it and a trench is formed in the silicon oxide layer. A degassing step is conducted under 330° C. to remove the moisture on the wafer. The wafer at the high degassing temperature is then directly placed into a rounding etching chamber, whereby a rounding etching step is performed to round the edge of the trench. The metal material can thus be easily filled into the trench in the following metal deposition process, so as to prevent the void being generated in the metal plug.

However, because of the high wafer temperature of 330° C. in the rounding etching process mentioned above, the surface of the silicon oxide layer to be etched has a higher activity, i.e., the Si—O valence bond at the surface is weaker. Therefore, when the surface of the silicon oxide layer is bombarded by the etching species, silicon oxide clusters are easily sputtered from the surface onto the inner surface of the etching chamber. When the silicon oxide deposited on the inner surface of the etching chamber reaches a certain amount, some of the silicon oxide will fall off to form particles and drop on the wafer surface.

### SUMMARY OF THE INVENTION

Accordingly, this invention provides a method for eliminating a particle source in order to increase the yield of the process.

The method for eliminating a particle source provided in this invention is suitably used in the etching process of a silicon oxide layer on the wafer. In this method, the wafer is degassed under a first temperature higher than the room temperature and then cooled down to a second temperature such as the room temperature. Thereafter, the silicon oxide layer is etched.

Since the temperature of the silicon oxide layer is lowered in this invention, the activity of its surface is lowered so that the sputtered silicon oxide is less and thereby the number of the particles can be reduced. Consequently, the yield of the process can be raised.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 shows the process flow of the method for eliminating a particle source according to a preferred embodiment of this invention; and

FIGS. 2, 3, and 4 each plots the number of the particles generated against the wafer number with an initial temperature of 550° C., 330° C., and 30° C. in the etching process.

### DESCRIPTION OF THE PREFERRED EMBODIMENTS

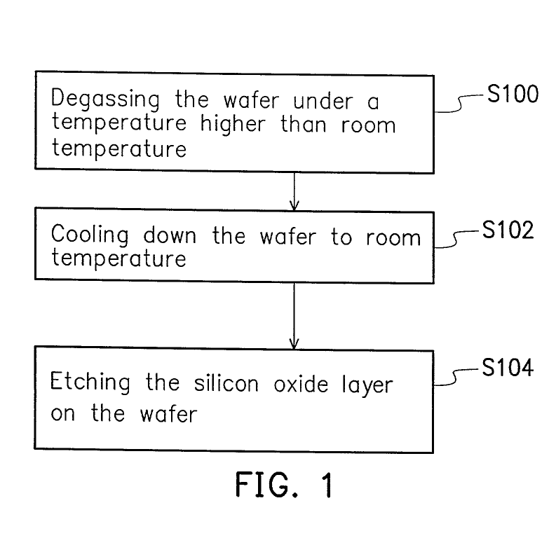

FIG. 1 shows the process flow of the method for eliminating a particle source according to a preferred embodiment of this invention. As shown in FIG. 1, a wafer with a silicon oxide layer on it is degassed under a temperature higher than the room temperature, such as 330° C., so as to remove the moisture on the wafer (S100). The wafer may be the one just cleaned by distilled water or the one that has been exposed to the air for a long time so that some moisture has been adsorbed, while the silicon oxide layer may have a trench formed therein. Since the moisture in the wafer is removed, the subsequent process will not be affected.

Still referring to FIG. 1, the wafer is then cooled down to the room temperature (S102) by, for example, natural cooling.

Further referring to FIG. 1, the silicon oxide layer is then etched (S104) utilizing, for example, a rounding etching process with a plasma, which is intended to round the edge of the trench.

Since the wafer is cooled down to room temperature, the activity of the surface of the silicon oxide layer is lowered. Therefore, silicon oxide clusters are not easily sputtered from the surface of the silicon oxide layer by the etching species during the etching process and the amount of particles generated can be decreased.

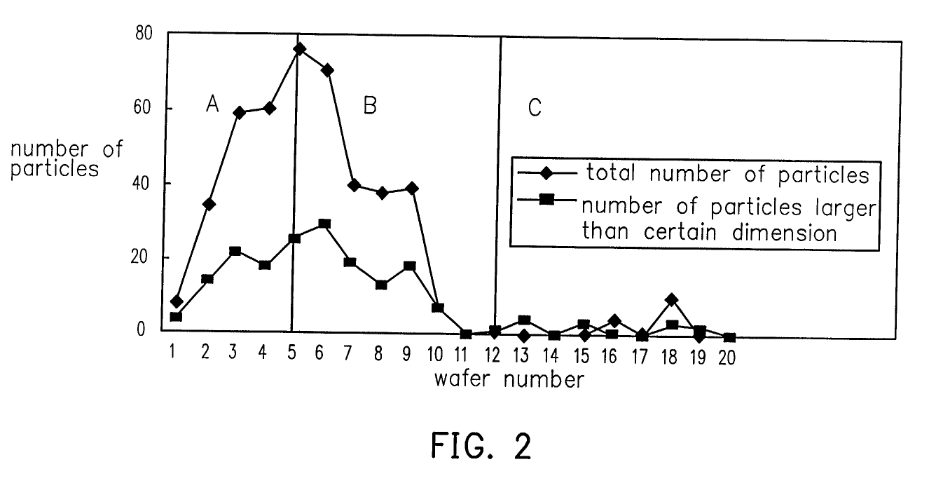

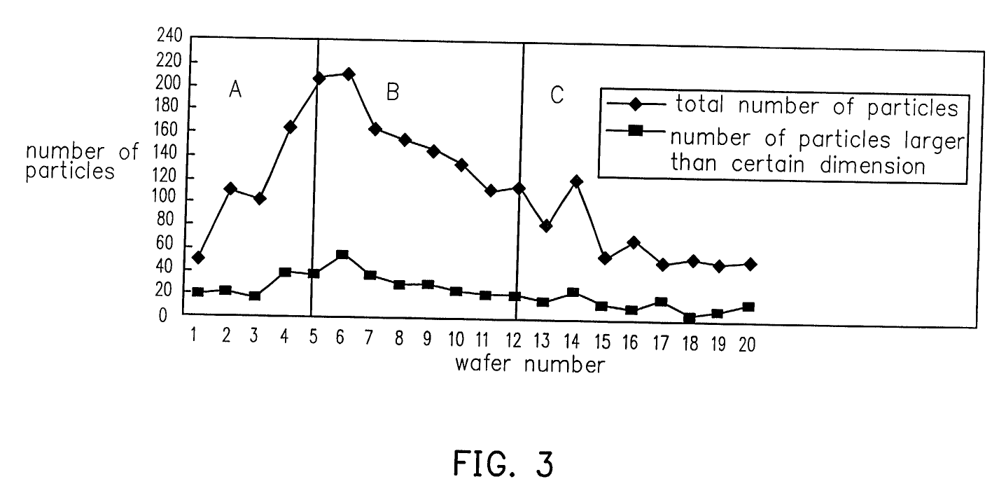

To further demonstrate the relationship between the wafer temperature and the amount of the particles generated during the etching process, dummy wafers are used for the test in the preferred embodiment of this invention. The dummy wafers are divided into three groups, wherein the dummy wafers in each group are etched with an individual initial temperature and then measured for the number of the particles generated. Refer to FIGS. 2, 3, and 4, each of which plots the number of the particles against the wafer number with an initial temperature of 550° C., 330° C., and 30° C. in the etching process. The diamond-shaped symbol represents the total number of the particles and the square-shaped symbol represents the number of the particles larger than a certain dimension.

In each of FIGS. 2˜4, the wafers in region A serve as contrastive examples, which are degassed under about 330° C., heated to about 550° C. in a heating chamber, and then placed in an etching chamber for the etching of the silicon oxide layer. The wafers in region B are treated by the conventional method, i.e., they are degassed under about 330° C. and then immediately placed in an etching chamber for the etching of the silicon oxide layer. The wafers in region C are degassed under about 330° C., cooled down to about 30° C. (˜room temperature), and then placed in an etching chamber for etching the silicon oxide layer according to this invention.

Refer to FIG. 2, the total number of the particles and the number of the particles larger than a certain dimension on the wafer in region A and region B are both larger than those on the wafer in region C. This is attributed to the higher activity of the surface of the silicon oxide layer, i.e., the weaker Si—O valence bond of the silicon oxide layer under a much higher temperature (regions A and B). In detail, when the surface of the silicon oxide layer is bombarded by the etching species under a high temperature, silicon oxide clusters are easily sputtered from the surface onto the inner surface of the etching chamber because of the weaker Si—O bond. When the silicon oxide deposited on the inner surface of the etching chamber reaches to a certain amount, some of the silicon oxide will fall off to form particles on the wafer surface.

On the other hand, when the wafer has a lower temperature (region C), the activity of the silicon oxide layer is lower and the Si—O valence bond is stronger. Therefore, when the surface of the silicon oxide layer is bombarded by the etching species, silicon oxide clusters are not easily sputtered from the surface and the amount of particles can be much decreased, so as to increase the yield of the process.

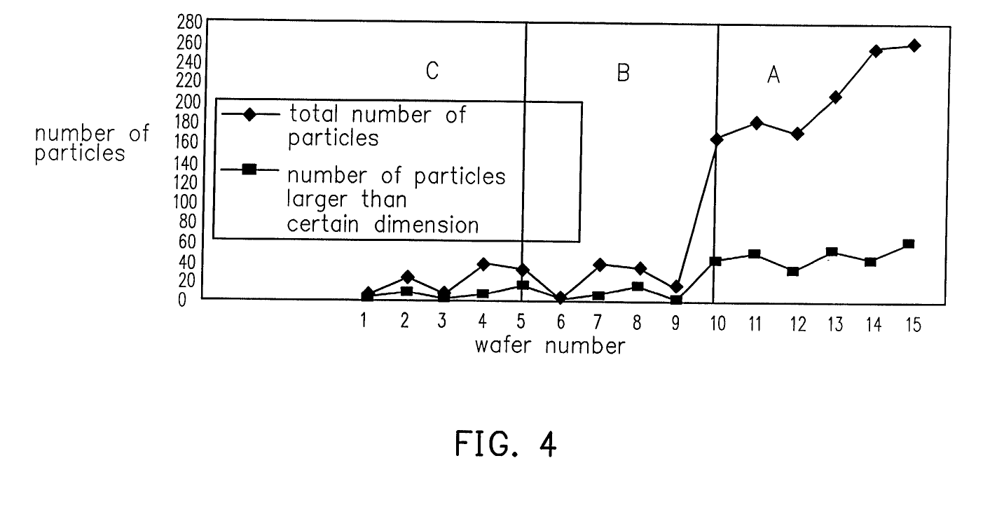

Moreover, as shown in FIGS. 2˜4, the effect of eliminating the particle source is observed regardless the order of the batch of the wafers being produced and tested. For example, in FIG. 4, the batch of wafers of region C is produced first and tested for the number of particles, followed by the production and the testing of the wafers of region B and then the wafers of region A. This fact further demonstrates that cooling the wafer before the etching process can decrease the amount of the particles generated. Since the amount of the particles generated is decreased, the yield of the process can be increased.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for eliminating a particle source, which is suitably used in an etching process of a silicon oxide layer on a wafer, comprising the steps of:
degassing the wafer under a first temperature higher than a room temperature;
cooling down the wafer to a second temperature; and
etching the silicon oxide layer.

2. The method of claim 1, wherein the silicon oxide layer comprises chemical vapor deposited (CVD) silicon oxide.

3. The method of claim 1, wherein the first temperature is about 330° C.

4. The method of claim 1, wherein the second temperature is a room temperature.

5. A method for eliminating a particle source, which is suitably used in an rounding etching process of a trench within a silicon oxide layer on a wafer, comprising the steps of:
degassing the wafer under a first temperature higher than a room temperature;
cooling down the wafer to a second temperature; and
etching the silicon oxide layer to round an edge of the trench.

6. The method of claim 5, wherein the silicon oxide layer comprises chemical vapor deposited (CVD) silicon oxide.

7. The method of claim 5, wherein the first temperature is about 330° C.

8. The method of claim 5, wherein the second temperature is a room temperature.
